(19) United States
(12) Patent Application Publication
(10) Pub. No.: US 2026/0129777 A1
(43) Pub. Date: May 7, 2026

(54) ANTENNA DEVICE AND CABLE WITHDRAWAL STRUCTURE

(71) Applicant: YOKOWO CO., LTD., Chiyoda-ku, Tokyo (JP)

(72) Inventor: Kenji HAYAKAWA, Tomioka-shi, Gunma (JP)

(73) Assignee: YOKOWO CO., LTD., Chiyoda-ku, Tokyo (JP)

(21) Appl. No.: 18/695,372

(22) PCT Filed: Aug. 17, 2022
(86) PCT No.: PCT/JP2022/031024

§ 371 Date: Mar. 26, 2024

(30) Foreign Application Priority Data
Sep. 27, 2021 (JP) 2021-156279

(51) Int. Cl. H05K 5/02; H01Q 1/42; H01Q 21/28

(52) U.S. Cl. CPC H05K 5/0247; H01Q 1/42; H01Q 21/28

(57) ABSTRACT

An antenna device including a case; a first antenna accommodated in the case; a first antenna substrate provided with the first antenna; and a first cable connected to the first antenna substrate, in which each of a plurality of first side surfaces of the case is provided with a first insertion hole allowing withdrawal of the first cable, and the first antenna substrate allows a withdrawal direction of the first cable to be changed with respect to the first insertion hole of each of the plurality of first side surfaces.

### TECHNICAL FIELD

The present invention relates to an antenna device and a cable withdrawal structure.

### BACKGROUND ART

In recent years, various antenna devices have been developed. For example, an antenna device disclosed in Patent Document 1 includes a Global Positioning System (GPS) antenna, an Electronic Toll Collection System (ETC) antenna, a case, and a base member. The GPS antenna and the ETC antenna are accommodated in the case. A GPS cable is connected to the GPS antenna. An ETC cable is connected to the ETC antenna. Guide grooves for guiding the GPS cable and the ETC cable are provided on a lower surface of the base member. The guide grooves allow withdrawal of the GPS cable and the ETC cable in three directions of a rear side, a left side, and a right side of the case.

### RELATED DOCUMENT

### Patent Document

Patent Document 1: Japanese Unexamined Patent Publication No. 2008-271270

### SUMMARY OF THE INVENTION

### Technical Problem

For example, the antenna device disclosed in Patent Document 1 has a structure to withdraw two cables of the GPS cable and the ETC cable in three directions on the same surface by the guide grooves. Accordingly, there is room for further improving the degree of freedom of the routing of the cable, for example, because of difficult routing for allowing the two cables to intersect. There is also room for further improving workability of the routing of the cables, for example, because of relatively complicated routing for inserting the two cables into the guide grooves.

An example of an object of the present invention is to improve a degree of freedom and the workability of the routing of a cable. Other objects of the present invention will become apparent from the description of the present specification.

### Solution to Problem

An aspect of the present invention is an antenna device including:
a case;
a first antenna accommodated in the case;
a first antenna substrate provided with the first antenna; and
a first cable connected to the first antenna substrate,
in which each of a plurality of first side surfaces of the case is provided with a first insertion hole allowing withdrawal of the first cable, and
the first antenna substrate allows a withdrawal direction of the first cable to be changed with respect to the first insertion hole of each of the plurality of first side surfaces.

An aspect of the present invention is a cable withdrawal structure to withdraw a first cable from a case, the first cable being connected to a first antenna substrate provided with a first antenna, the case accommodating the first antenna and the first antenna substrate, the cable withdrawal structure including:
a first insertion hole provided in each of a plurality of first side surfaces of the case, the first insertion hole allowing withdrawal of the first cable; and
a change portion provided on at least the first antenna substrate and allowing a withdrawal direction of the first cable to be changed with respect to the first insertion hole of each of the plurality of first side surfaces.

According to the above aspects of the present invention, it is possible to improve a degree of freedom and the workability in routing a cable.

### BRIEF DESCRIPTION OF THE DRAWINGS

FIG. 1 An exploded perspective view of an antenna device according to an embodiment.

FIG. 2 An exploded perspective view of a part of the antenna device according to the embodiment as viewed from below.

FIG. 3 A view for describing a method of withdrawing two first cables from a first right side surface portion in a cable withdrawal structure according to the embodiment.

FIG. 4 A view for describing a method of withdrawing two first cables from a first rear side surface portion in the cable withdrawal structure according to the embodiment.

FIG. 5 A view for describing a method of withdrawing two first cables from a first left side surface portion in the cable withdrawal structure according to the embodiment.

FIG. 6 A bottom view of the antenna device with two first cables and one second cable withdrawn from the first right side surface portion.

FIG. 7 A right side view of the antenna device with two first cables and one second cable withdrawn from the first right side surface portion.

### DESCRIPTION OF EMBODIMENTS

Hereinafter, an embodiment of the present invention will be described with reference to the drawings. In all drawings, similar components are denoted by the similar reference signs, and description thereof will not be repeated.

In the present specification, ordinal numbers such as “first”, “second”, and “third” are added to simply distinguish components having similar names unless otherwise specified, and do not mean the particular feature of the component (for example, order or importance).

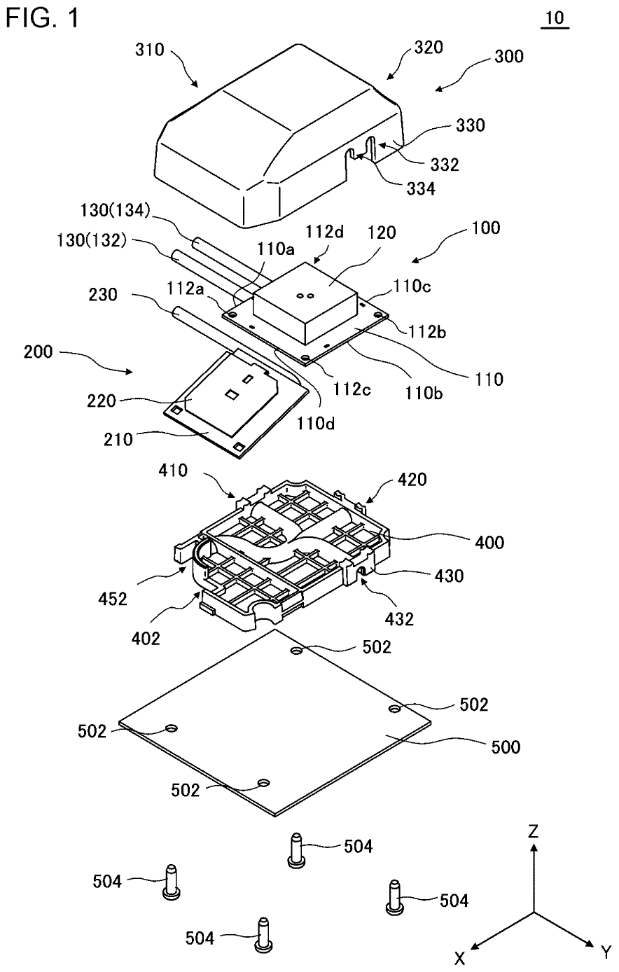

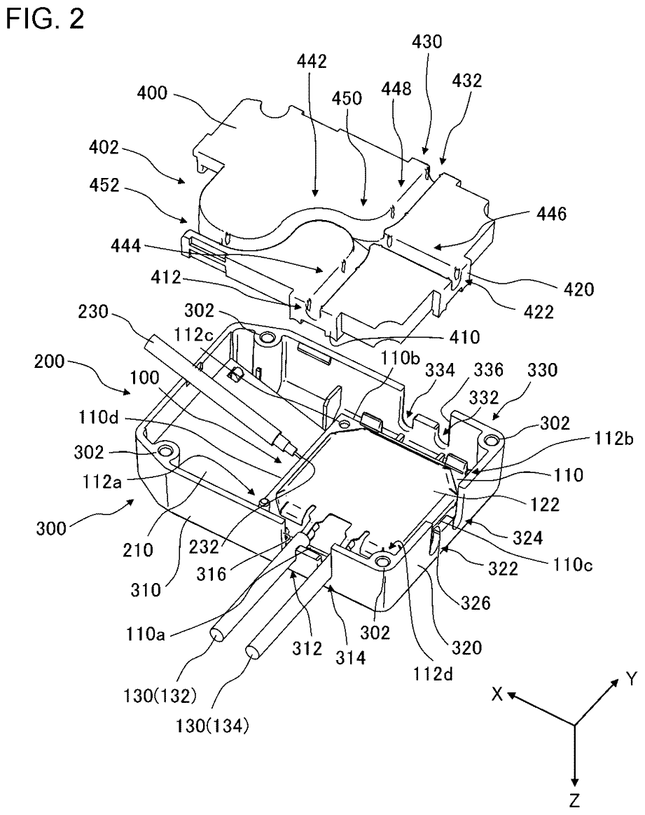

FIG. 1 is an exploded perspective view of an antenna device 10 according to the embodiment. FIG. 2 is an exploded perspective view of a part of the antenna device 10 according to the embodiment as viewed from below.

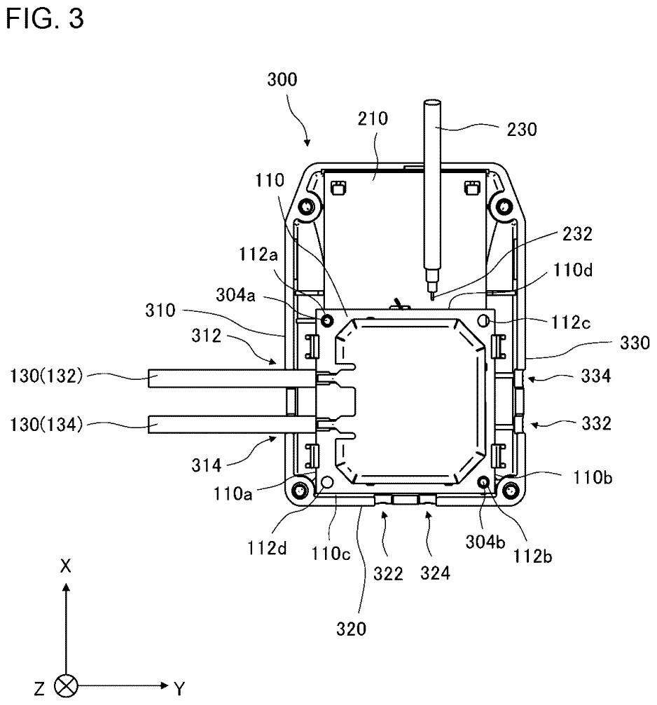

In FIGS. 1 and 2, an arrow indicating a first direction X, a second direction Y, or a third direction Z indicates that a direction from a base to a tip of the arrow is a positive direction of the direction indicated by the arrow, and that a direction from the tip to the base of the arrow is a negative direction of the direction indicated by the arrow. The same applies to FIGS. 3 to 7 to be described below.

The positive direction of the first direction X is a direction from the rear side to the front side of the antenna device 10. The negative direction of the first direction X is a direction from the front side to the rear side of the antenna device 10. The positive direction of the second direction Y is a direction from the right side to the left side of the antenna device 10 with a case 300 positioned above a bracket 500 when viewed from the rear side of the antenna device 10. The negative direction of the second direction Y is a direction from the left side to the right side of the antenna device 10 with the case 300 positioned above the bracket 500 when viewed from the rear side of the antenna device 10. The positive direction of the third direction Z is a direction from the lower side to the upper side of the antenna device 10. The negative direction of the antenna device 10 is a direction from the upper side to the lower side of the antenna device 10.

Hereinafter, unless otherwise specified, “right” and “left” mean the right and the left, respectively, with the case 300 positioned above the bracket 500 when viewed from the rear side of the antenna device 10.

As illustrated in FIG. 1, the antenna device 10 includes a first antenna unit 100, a second antenna unit 200, the case 300, a base member 400, and the bracket 500.

As illustrated in FIG. 1, the first antenna unit 100 includes a first antenna substrate 110, a first antenna 120, and two first cables 130. As illustrated in FIG. 2, the first antenna unit 100 further includes a shield cover 122. In the present embodiment, the two first cables 130 are cables for a global navigation satellite system (GNSS) antenna, and include a first GNSS cable 132 and a second GNSS cable 134. Note that the two first cables 130 are not limited to the cables for the GNSS antenna. For example, the two first cables 130 may be cables for a Sirius XM (SXM) antenna.

The first antenna substrate 110 has a thickness in a vertical direction. The first antenna 120 is provided on an upper surface of the first antenna substrate 110. In the present embodiment, the shape of the first antenna substrate 110 when viewed from the third direction Z is substantially square. Specifically, as illustrated in FIGS. 1 and 2, the first antenna substrate 110 has a first side 110a, a second side 110b, a third side 110c, and a fourth side 110d. The first GNSS cable 132 and the second GNSS cable 134 are withdrawn from the first side 110a side. The second side 110b is opposite to the first side 110a. The third side 110c and the fourth side 110d are opposite sides different from the first side 110a and the second side 110b. Specifically, the third side 110c is positioned on the left side of the center of the first antenna substrate 110 with the first antenna 120 positioned above the first antenna substrate 110 when viewed from the first side 110a side. The fourth side 110d is positioned on the right side of the center of the first antenna substrate 110 with the first antenna 120 positioned above the first antenna substrate 110 when viewed from the first side 110a side.

As illustrated in FIGS. 1 and 2, a first hole 112a is provided at a corner portion where the first side 110a and the fourth side 110d of the first antenna substrate 110 intersect. A second hole 112b is provided at a corner portion where the second side 110b and the third side 110c of the first antenna substrate 110 intersect. A third hole 112c is provided at a corner portion where the second side 110b and the fourth side 110d of the first antenna substrate 110 intersect. A fourth hole 112d is provided at a corner portion where the first side 110a and the third side 110c of the first antenna substrate 110 intersect. When viewed from a direction parallel to a thickness direction of the first antenna substrate 110, the first hole 112a, the second hole 112b, the third hole 112c, and the fourth hole 112d are arranged symmetrically with respect to the center of the first antenna substrate 110.

As illustrated in FIG. 1, the first antenna 120 is an antenna element including a radiating element, a dielectric substrate, a feeding element, and the like. The first antenna 120 is electrically connected to the first antenna substrate 110. In the present embodiment, the first antenna 120 is a GNSS antenna. The first antenna 120, however, may be an antenna for a purpose different from GNSS. The first antenna 120 is a patch antenna having a substantially square shape when viewed from the third direction Z. The first antenna 120 has a radiation directivity upward in the vertical direction (zenith direction).

As illustrated in FIG. 2, the shield cover 122 is provided on a lower surface of the first antenna substrate 110. Specifically, an unillustrated ground electrode is provided on at least a portion of the lower surface side of the first antenna substrate 110. The ground electrode is provided, for example, on substantially the entire lower surface side of the first antenna substrate 110. An unillustrated low noise amplifier circuit is provided on the lower surface side of the first antenna substrate 110. The shield cover 122 covers the low noise amplifier circuit.

The first GNSS cable 132 and the second cable 134 are connected to the first antenna substrate 110. As illustrated in FIGS. 1 and 2, on the first side 110a side, the first GNSS cable 132 is withdrawn from a side where the fourth side 110d is located relative to the center of the first side 110a. On the first side 110a, the second GNSS cable 134 is withdrawn from a side where the third side 110c is located relative to the center of the first side 110a.

The first antenna 120 is configured to radiate radio waves due to a feeding signal supplied through the first GNSS cable 132 and the first antenna substrate 110, and to send a satellite signal received from the outside to an information processing device such as an unillustrated navigation device through the first antenna substrate 110 and the first GNSS cable 132 or the second GNSS cable 134. Note that, for example, the first GNSS cable 132 is connected to an unillustrated navigation device, and the second GNSS cable 134 is connected to an unillustrated telematics unit.

As illustrated in FIG. 1, the second antenna unit 200 has a second antenna substrate 210, a second antenna 220, and a second cable 230.

As illustrated in FIG. 1, the second antenna substrate 210 is inclined obliquely upward and forward with respect to a plane perpendicular to the third direction Z. The second antenna 220 is provided on the upper surface of the second antenna substrate 210. The upper surface of the second antenna substrate 210 is directed obliquely upward and forward.

As illustrated in FIG. 1, the second antenna 220 is, for example, a conductive plate, such as sheet metal. The second antenna 220 is electrically connected to the second antenna substrate 210. In the present embodiment, the second antenna 220 is an electronic toll collection system (ETC) antenna. The second antenna 220, however, may be an antenna for a purpose different from ETC. The upper surface of the second antenna 220 is directed obliquely upward and forward by the inclination of the upper surface of the second antenna substrate 210 with respect to the plane perpendicular to the third direction Z. The second antenna 220 has a radiation directivity in an obliquely upward and forward side.

The second cable 230 is connected to the second antenna substrate 210. In the present embodiment, as illustrated in FIG. 2, the second cable 230 has a first end 232 connected to the second antenna substrate 210. The first end 232 is positioned on the lower surface side of the second antenna substrate 210. The first end 232 is positioned on the positive direction side of the second direction Y with respect to the center of the second antenna substrate 210 in the second direction Y. Note that the first end 232 is connected to a side of the second antenna 220 closer to the first antenna substrate 110 when the second antenna 220 is accommodated in the case 300. The second cable 230 of which the first end 232 is connected to the second antenna 220 extends from the first end 232 over a region of the second antenna 220, and is withdrawn through a first guide groove 442, a second guide groove 444, a third guide groove 446, and a fourth guide groove 448 of the base member 400, which will be described later. Note that FIG. 2 illustrates a part of the second cable 230 to illustrate the first end 232 connected to the second antenna 220. FIG. 1, on the other hand, illustrates a part of the second cable 230 withdrawn to the outside of the case 300.

The second antenna 220 is configured to radiate radio waves to the outside due to an electrical signal sent through the second cable 230 and the second antenna substrate 210.

As illustrated in FIGS. 1 and 2, the case 300 accommodates the first antenna substrate 110, the first antenna 120, the second antenna substrate 210, the second antenna 220, and the base member 400. The case 300 is a case made of resin having electromagnetic wave transmittance. The case 300 has a first right side surface portion 310, a first rear side surface portion 320, and a first left side surface portion 330. The first right side surface portion 310 is provided on the right side of the antenna device 10. The first right side surface portion 310 extends in a wall shape in the first direction X. The first rear side surface portion 320 is provided on the rear side of the antenna device 10. The first rear side surface portion 320 extends in the second direction Y in a wall shape connecting a rear end portion of the first right side surface portion 310 and a rear end portion of the first left side surface portion 330. The first left side surface portion 330 is provided on the left side of the antenna device 10. The first left side surface portion 330 extends in a wall shape in the first direction X. The first right side surface portion 310 and the first left side surface portion 330 have a substantially parallel positional relationship.

As illustrated in FIG. 2, the first right side surface portion 310 is provided with a first right insertion hole 312 and a second right insertion hole 314. The first right insertion hole 312 penetrates the first right side surface portion 310 of the case 300 in the second direction Y. The second right insertion hole 314 penetrates the first right side surface portion 310 of the case 300 in the second direction Y. The second right insertion hole 314 is positioned behind the first right insertion hole 312 in the negative direction of the first direction X. The first right insertion hole 312 is configured to allow withdrawal of the first GNSS cable 132 toward the right side of the case 300. The second right insertion hole 314 is configured to allow withdrawal of the second GNSS cable 134 toward the right side of the case 300. That is, the first right insertion hole 312 and the second right insertion hole 314 have the shape, size, and the like adapted to the shape, diameter, and the like of the first GNSS cable 132 and the second GNSS cable 134, respectively.

As illustrated in FIG. 2, a first notch 316 is provided at a lower end of the first right side surface portion 310 of the case 300. A portion of the upper end of the first notch 316 on the positive direction side of the first direction X communicates with the lower end of the first right insertion hole 312. A portion of the upper end of the first notch 316 on the negative direction side of the first direction X communicates with the lower end of the second right insertion hole 314.

As illustrated in FIG. 2, the first rear side surface portion 320 is provided with a first rear insertion hole 322 and a second rear insertion hole 324. The first rear insertion hole 322 penetrates the first rear side surface portion 320 of the case 300 in the first direction X. The second rear insertion hole 324 penetrates the first rear side surface portion 320 of the case 300 in the first direction X. The first rear insertion hole 322 is positioned on the negative direction side of the second direction Y with respect to the center of the first rear side surface portion 320 in the second direction Y. The second rear insertion hole 324 is positioned on the positive direction side of the second direction Y with respect to the center of the first rear side surface portion 320 in the second direction Y. The first rear insertion hole 322 is configured to allow withdrawal of the first GNSS cable 132 in the negative direction of the first direction X of the case 300. The second rear insertion hole 324 is configured to allow withdrawal of the second GNSS cable 134 in the negative direction of the first direction of the case 300. That is, the first rear insertion hole 322 and the second rear insertion hole 324 have the shape, size, and the like adapted to the shape, diameter, and the like of the first GNSS cable 132 and the second GNSS cable 134, respectively.

As illustrated in FIG. 2, a second notch 326 is provided at a lower end of the first rear side surface portion 320 of the case 300. A portion of the upper end of the second notch 326 on the negative direction side of the second direction Y with respect to the center in the second direction Y communicates with the lower end of the first rear insertion hole 322. A portion of the upper end of the second notch 326 on the positive direction side of the second direction Y with respect to the center in the second direction Y communicates with the lower end of the second rear insertion hole 324.

As illustrated in FIG. 2, the first left side surface portion 330 is provided with a first left insertion hole 332 and a second left insertion hole 334. The first left insertion hole 332 penetrates the first left side surface portion 330 of the case 300 in the second direction Y. The second left insertion hole 334 penetrates the first left side surface portion 330 of the case 300 in the second direction Y. The second left insertion hole 334 is positioned in front of the first left insertion hole 332 in the positive direction of the first direction X. The first left insertion hole 332 is configured to allow withdrawal of the first GNSS cable 132 toward the left side of the case 300. The second left insertion hole 334 is configured to allow withdrawal of the second GNSS cable 134 toward the left side of the case 300. That is, the first rear insertion hole 322 and the second rear insertion hole 324 have the shape, size, and the like adapted to the shape, diameter, and the like of the first GNSS cable 132 and the second GNSS cable 134, respectively.

As illustrated in FIG. 2, a third notch 336 is provided at a lower end of the first left side surface portion 330 of the case 300. A portion of the upper end of the third notch 336 on the negative direction side of the first direction X communicates with the lower end of the first left insertion hole 332. A portion of the upper end of the third notch 336 on the positive direction side of the first direction X communicates with the lower end of the second left insertion hole 334.

As illustrated in FIGS. 1 and 2, the base member 400 is positioned below at least a portion of the first antenna unit 100 and the second antenna unit 200. The base member 400 has a second right side surface portion 410, a second rear side surface portion 420, and a second left side surface portion 430.

As illustrated in FIG. 2, the second right side surface portion 410 protrudes toward the negative direction of the second direction Y from the peripheral portion of the second right side surface portion 410 on the side surface of the base member 400 on the negative direction side of the second direction Y. On the side surface of the base member 400 on the negative direction side of the second direction Y, the second right side surface portion 410 protruding toward the negative direction of the second direction Y from the peripheral portion thereof forms a convex portion having the second right side surface portion 410 as a tip surface. The convex portion fits into the first notch 316 with the case 300 covering the base member 400. If the convex portion fits into the first notch 316, at least a portion of the second right side surface portion 410 is exposed from the first right side surface portion 310 through the first notch 316. Accordingly, the height of the antenna device 10 in the third direction Z can be reduced as compared with a case where the base member 400 is positioned below the lower end of the case 300. When the case 300 covers the base member 400, the second right side surface portion 410 is provided on the same side surface side as the first right side surface portion 310. Furthermore, when the case 300 covers the base member 400, the second right side surface portion 410 is flush with the first right side surface portion 310.

As illustrated in FIG. 2, the second right side surface portion 410 is provided with a third right insertion hole 412. The second right side surface portion 410 fitting into the first notch 316 positions the first right insertion hole 312, the second right insertion hole 314, and the third right insertion hole 412 on the same side surface side of the case 300. The third right insertion hole 412 communicates with the other end of the second guide groove 444 as described below opposite to one end of the second guide groove 444 connected to a branch portion 450. The third right insertion hole 412 is configured to allow withdrawal of the second cable 230 toward the right side of the base member 400. That is, the third right insertion hole 412 has the shape, size, and the like adapted to the shape, diameter, and the like of the second cable 230.

As illustrated in FIG. 2, the second rear side surface portion 420 protrudes toward the negative direction of the first direction X from the peripheral portion of the second rear side surface portion 420 on the side surface of the base member 400 on the negative direction side of the first direction X. On the side surface of the base member 400 on the negative direction side of the first direction X, the second rear side surface portion 420 protruding toward the negative direction of the first direction X from the peripheral portion thereof forms a convex portion having the second rear side surface portion 420 as a tip surface. The convex portion fits into the second notch 326 with the case 300 covering the base member 400. If the convex portion fits into the second notch 326, at least a portion of the second rear side surface portion 420 is exposed from the first rear side surface portion 320 through the second notch 326. Accordingly, the height of the antenna device 10 in the third direction Z can be reduced as compared with a case where the base member 400 is positioned below the lower end of the case 300. When the case 300 covers the base member 400, the second rear side surface portion 420 is provided on the same side surface side as the first rear side surface portion 320. Furthermore, when the case 300 covers the base member 400, the second rear side surface portion 420 is flush with the first rear side surface portion 320.

As illustrated in FIG. 2, the second rear side surface portion 420 is provided with a third rear insertion hole 422. The second rear side surface portion 420 fitting into the second notch 326 positions the first rear insertion hole 322, the second rear insertion hole 324, and the third rear insertion hole 422 on the same side surface side of the case 300. The third rear insertion hole 422 communicates with the other end of the third guide groove 446 as described below opposite to one end of the third guide groove 446 connected to the branch portion 450. The third rear insertion hole 422 is configured to allow withdrawal of the second cable 230 in the negative direction of the first direction X of the base member 400. That is, the third rear insertion hole 422 has the shape, size, and the like adapted to the shape, diameter, and the like of the second cable 230.

As illustrated in FIG. 2, the second left side surface portion 430 protrudes toward the positive direction of the second direction Y from the peripheral portion of the second left side surface portion 430 on the side surface of the base member 400 on the positive direction side of the second direction Y. On the side surface of the base member 400 on the positive direction side of the second direction Y, the second left side surface portion 430 protruding toward the positive direction of the second direction Y from the peripheral portion thereof forms a convex portion having the second left side surface portion 430 as a tip surface. The convex portion fits into the third notch 336 with the case 300 covering the base member 400. If the convex portion fits into the third notch 336, at least a portion of the second left side surface portion 430 is exposed from the first left side surface portion 330 through the third notch 336. Accordingly, the height of the antenna device 10 in the third direction Z can be reduced as compared with a case where the base member 400 is positioned below the lower end of the case 300. When the case 300 covers the base member 400, the second left side surface portion 430 is provided on the same side surface side as the first left side surface portion 330. Furthermore, when the case 300 covers the base member 400, the second left side surface portion 430 is flush with the first left side surface portion 330.

As illustrated in FIG. 2, the second left side surface portion 430 is provided with a third left insertion hole 432.

The second left side surface portion 430 fitting into the third notch 336 positions the first left insertion hole 332, the second left insertion hole 334, and the third left insertion hole 432 on the same side surface side of the case 300. The third left insertion hole 432 communicates with the other end of the fourth guide groove 448 as described below opposite to one end of the fourth guide groove 448 connected to the branch portion 450. The third left insertion hole 432 is configured to allow withdrawal of the second cable 230 toward the left side of the base member 400. That is, the third left insertion hole 432 has the shape, size, and the like adapted to the shape, diameter, and the like of the second cable 230.

Note that the tip of the convex portion on the side close to the two first cables 130 has an arc shape to match the shape of the two first cables 130 withdrawn from each insertion hole on each side surface of the case 300 when each convex portion described above fits into each notch portion, for example. The two first cables 130 can be stabilized with respect to the case by making the tip of each convex portion on a side close to the two first cables 130 have an arc shape matching the shape of the first cable 130.

As illustrated in FIG. 2, the first guide groove 442, the second guide groove 444, the third guide groove 446, and the fourth guide groove 448 are provided on the lower surface of the base member 400.

The first guide groove 442 extends from a front insertion hole 452 to the branch portion 450. The front insertion hole 452 communicates with a fourth notch 402 provided on an edge of the base member 400 in the positive direction of the first direction X. On the edge of the base member 400 in the positive direction of the first direction X, the fourth notch 402 is provided on the negative direction side of the second direction Y with respect to the center of the base member 400 in the second direction Y. At the branch portion 450, the first guide groove 442 branches into the second guide groove 444, the third guide groove 446, and the fourth guide groove 448. On the negative direction of the first direction X with respect to the front insertion hole 452, the branch portion 450 is positioned at the substantial center of the base member 400 in the second

The second guide groove 444 extends from the branch portion 450 to the third right insertion hole 412. One end of the second guide groove 444 on the branch portion 450 side communicates with one end of the first guide groove 442 on the branch portion 450 side. The other end of the second guide groove 444 on the third right insertion hole 412 side communicates with the third right insertion hole 412.

The third guide groove 446 extends from the branch portion 450 to the third rear insertion hole 422. One end of the third guide groove 446 on the branch portion 450 side communicates with one end of the first guide groove 442 on the branch portion 450 side. The other end of the third guide groove 446 on the third rear insertion hole 422 side communicates with the third rear insertion hole 422.

The fourth guide groove 448 extends from the branch portion 450 to the third left insertion hole 432. One end of the fourth guide groove 448 on the branch portion 450 side communicates with one end of the first guide groove 442 on the branch portion 450 side. The other end of the fourth guide groove 448 on the third left insertion hole 432 side communicates with the third left insertion hole 432. Note that all of the first guide groove 442, the second guide groove 444, the third guide groove 446, and the fourth guide groove 448 have the shape, size, and the like adapted to the shape, diameter, and the like of the second cable 230 to make the second cable 230 fit.

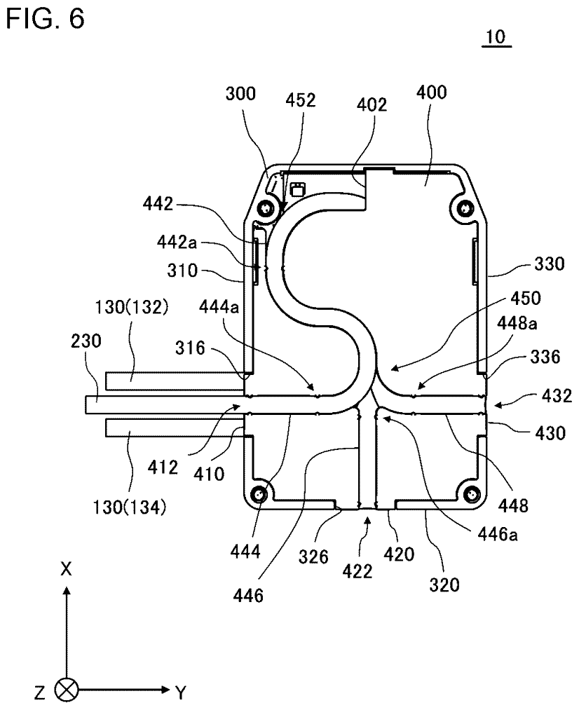

As illustrated in FIG. 1, the bracket 500 is provided below the case 300 and the base member 400. The bracket 500 is, for example, a steel plate. Four through-holes 502 are provided in four portions of the bracket 500 around the four corners of the base member 400. A screw 504 penetrates each through-hole 502 from below the bracket 500. As illustrated in FIG. 2, the case 300 is provided with four attachment holes 302. The upper end of each of the four screws 504 is inserted into each of the four attachment holes 302. As described later with reference to FIG. 6, the second cable 230 is guided from the first guide groove 442 to the second guide groove 444, the third guide groove 446, or the fourth guide groove 448, and is withdrawn from the third right insertion hole 412, the third rear insertion hole 422, or the third left insertion hole 432. The bracket 500 is attached to the case 300 with the second cable 230 guided from the first guide groove 442 to the second guide groove 444, the third guide groove 446, or the fourth guide groove 448, and withdrawn from the third right insertion hole 412, the third rear insertion hole 422, or the third left insertion hole 432. Accordingly, the bracket 500 can prevent the second cable 230 from falling out from the first guide groove 442, the second guide groove 444, the third guide groove 446, and the fourth guide groove 448 to the lower side of the base member 400.

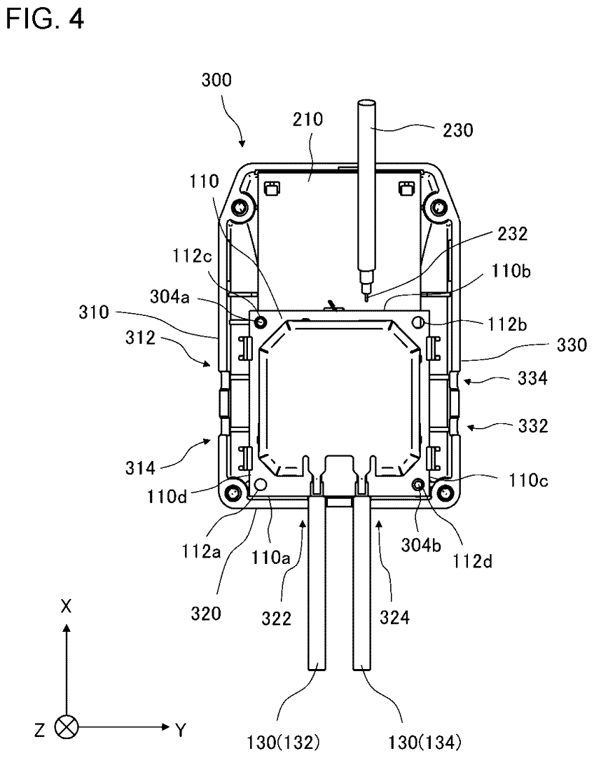

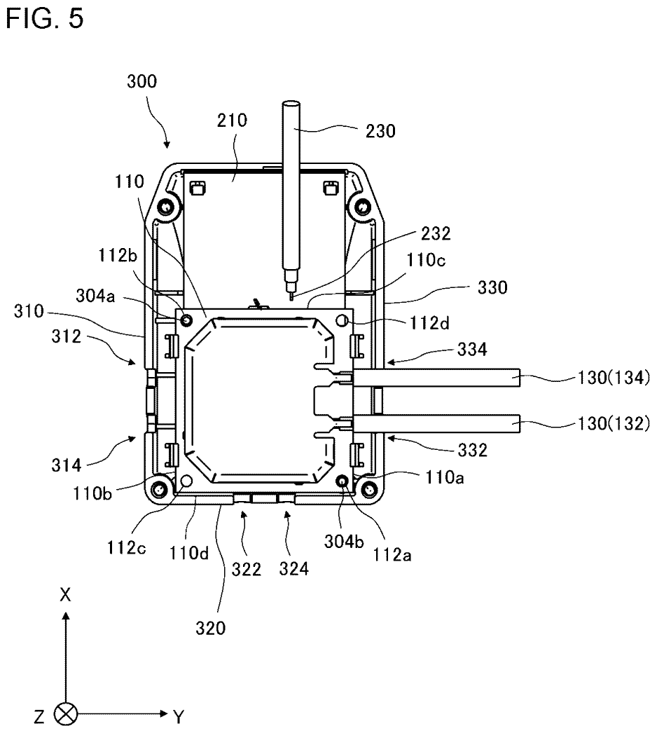

FIG. 3 is a view for describing a method of withdrawing the two first cables 130 from the first right side surface portion 310 in a cable withdrawal structure according to the embodiment. FIG. 4 is a view for describing a method of withdrawing the two first cables 130 from the first rear side surface portion 320 in the cable withdrawal structure according to the embodiment. FIG. 5 is a view for describing a method of withdrawing the two first cables 130 from the first left side surface portion 330 in the cable withdrawal structure according to the embodiment.

In FIGS. 3 to 5, an X-marked circle indicating the third direction Z indicates that a direction from the foreground to the background of the paper plane is the positive direction of the third direction Z and that a direction from the background to the foreground of the paper plane is the negative direction of the third direction Z.

As illustrated in FIGS. 3 to 5, a first protrusion 304a and a second protrusion 304b are provided inside the case 300. The first protrusion 304a and the second protrusion 304b protrude from the positive direction of the third direction Z toward the negative direction of the third direction Z of the case 300. The first protrusion 304a is positioned on the negative direction side of the second direction Y with respect to the center of the case 300 in the second direction Y. The second protrusion 304b is positioned on the positive direction side of the second direction Y with respect to the center of the case 300 in the second direction Y. The position of the second protrusion 304b in the first direction X is positioned on the negative direction side of the first direction X with respect to the position of the first protrusion 304a in the first direction X. That is, the second protrusion 304b is positioned on the negative direction side in the first direction X with respect to the first protrusion 304a in the projection having the first protrusion 304a and the second protrusion 304b projected in parallel with the second direction Y onto a virtual plane perpendicular to the second direction Y.

As illustrated in FIG. 3, when the two first cables 130 are withdrawn from the first right side surface portion 310, the first protrusion 304a of the case 300 is inserted into the first hole 112a of the first antenna substrate 110, and the second protrusion 304b of the case 300 is inserted into the second hole 112b of the first antenna substrate 110. Thus, the first antenna substrate 110 is attached to the case 300 with the first side 110a of the first antenna substrate 110 directed to the side of the case 300 where the first right side surface portion 310 is positioned. Accordingly, the first GNSS cable 132 is withdrawable from the first right insertion hole 312. The second GNSS cable 134 is withdrawable from the second right insertion hole 314.

In the example illustrated in FIG. 3, the first protrusion 304a and the second protrusion 304b are respectively inserted into the first hole 112a and the second hole 112b, which are two holes positioned diagonally of the first antenna substrate 110. Accordingly, the first antenna substrate 110 can be stably attached to the case 300 as compared with a case where the first protrusion 304a and the second protrusion 304b are inserted into two holes positioned at two adjacent corner portions of the first antenna substrate 110.

As illustrated in FIG. 4, when the two first cables 130 are withdrawn from the first rear side surface portion 320, the first protrusion 304a of the case 300 is inserted into the third hole 112c of the first antenna substrate 110, and the second protrusion 304b of the case 300 is inserted into the fourth hole 112d of the first antenna substrate 110. The first antenna substrate 110 is attached to the case 300 with the first side 110a of the first antenna substrate 110 directed to the side of the case 300 where the first rear side surface portion 320 is positioned. Accordingly, the first GNSS cable 132 is withdrawable from the first rear insertion hole 322. The second GNSS cable 134 is withdrawable from the second rear insertion hole 324.

In the example illustrated in FIG. 4, the first protrusion 304a and the second protrusion 304b are respectively inserted into the third hole 112c and the fourth hole 112d, which are two holes positioned diagonally of the first antenna substrate 110. Accordingly, the first antenna substrate 110 can be stably attached to the case 300 as compared with a case where the first protrusion 304a and the second protrusion 304b are inserted into two holes positioned at two adjacent corner portions of the first antenna substrate 110.

As illustrated in FIG. 5, when the two first cables 130 are withdrawn from the first left side surface portion 330, the first protrusion 304a of the case 300 is inserted into the second hole 112b of the first antenna substrate 110, and the second protrusion 304b of the case 300 is inserted into the first hole 112a of the first antenna substrate 110. The first antenna substrate 110 is attached to the case 300 with the first side 110a of the first antenna substrate 110 directed to the side of the case 300 where the first left side surface portion 330 is positioned. Accordingly, the first GNSS cable 132 is withdrawable from the first left insertion hole 332. The second GNSS cable 134 is withdrawable from the second left insertion hole 334.

In the example illustrated in FIG. 5, the first protrusion 304a and the second protrusion 304b are respectively inserted into the second hole 112b and the first hole 112a, which are two holes positioned diagonally of the first antenna substrate 110. Accordingly, the first antenna substrate 110 can be stably attached to the case 300 as compared with a case where the first protrusion 304a and the second protrusion 304b are inserted into two holes positioned at two adjacent corner portions of the

The first hole 112a and the second hole 112b of the first antenna substrate 110 and the first protrusion 304a and the second protrusion 304b of the case 300 have a function of positioning the two first cables 130 with the first right insertion hole 312 and the second right insertion hole 314. The first hole 112a and the second hole 112b of the first antenna substrate 110 and the first protrusion 304a and the second protrusion 304b of the case 300 have a function of positioning the two first cables 130 with the first left insertion hole 332 and the second left insertion hole 334. The third hole 112c and the fourth hole 112d of the first antenna substrate 110 and the first protrusion 304a and the second protrusion 304b of the case 300 have a function of positioning the two first cables 130 with the first rear insertion hole 322 and the second rear insertion hole 324. That is, each of the two first cables 130 and each insertion hole are positioned by inserting each protrusion of the case 300 into each hole of the first antenna substrate 110. Note that the first hole 112a, the second hole 112b, the third hole 112c, and the fourth hole 112d of the first antenna substrate 110 in the present embodiment function as a change portion allowing the withdrawal direction of the two first cables 130 to be changed with respect to each insertion hole. The first hole 112a, the second hole 112b, the third hole 112c, and the fourth hole 112d of the first antenna substrate 110 in the present embodiment allow the withdrawal direction of the two first cables 130 to be changed with the two first cables 130 connected to the first antenna substrate 110.

As described with reference to FIGS. 3 to 5, in the cable withdrawal structure according to the present embodiment, the withdrawal direction of the two first cables 130 can be changed to the right side, the rear side, or the left side of the case 300 depending on which of first right insertion hole 312 and the second right insertion hole 314, the first rear insertion hole 322 and the second rear insertion hole 324, or the first left insertion hole 332 and the second left insertion hole 334 the two first cables 130 are withdrawn from. Which insertion hole in the plurality of side surfaces including the first right side surface portion 310, the first rear side surface portion 320, and the first left side surface portion 330 of the case 300 the two first cables 130 are withdrawn from is changeable by the first antenna substrate 110. Accordingly, the degree of freedom and the workability of the routing of the two first cables 130 can be improved because the withdrawal direction of the two first cables 130 can be easily changed.

Specifically, in the cable withdrawal structure according to the present embodiment, the first antenna substrate 110 has a shape to allow the attachment to the first protrusion 304a and the second protrusion 304b when the first GNSS cable 132 and the second GNSS cable 134 are withdrawn from any of the first right insertion hole 312 and the second right insertion hole 314, the first rear insertion hole 322 and the second rear insertion hole 324, or the first left insertion hole 332 and the second left insertion hole 334. Accordingly, the withdrawal direction of the two first cables 130 can be changed to the right side, the rear side, or the left side of the case 300 by changing the orientation of the first antenna substrate 110 with respect to the case 300.

As described with reference to FIGS. 3 to 5, in the cable withdrawal structure according to the present embodiment, the two first cables 130 can be withdrawn from the case 300 without through the guide grooves provided on the lower surface of the base member 400. It is therefore not necessary to route the two first cables 130 and the second cable 230 on the same surface of the guide grooves provided on the lower surface of the base member 400. Accordingly, variations in the routing of the two first cables 130 and the one second cable 230 can be increased as compared with a case where the two first cables 130 pass through the guide grooves provided on the lower surface of the base member 400.

As described with reference to FIGS. 3 to 5, in the cable withdrawal structure according to the present embodiment, the two first cables 130 can be withdrawn straight from the first antenna 120 through any of the first right insertion hole 312 and the second right insertion hole 314, the first rear insertion hole 322 and the second rear insertion hole 324, or the first left insertion hole 332 and the second left insertion hole 334. Accordingly, it is possible to suppress a fluctuation in the characteristics of the first antenna 120 caused by bending the two first cables 130.

The withdrawal direction of the two first cables 130 is not limited to the right side, the rear side, or the left side of the case 300. For example, the two first cables 130 may be withdrawn in another direction of the case 300, such as the front side, the upper side, the right oblique rear side, or the left oblique front side. The withdrawal direction of each first cable 130 can be changed depending on the orientation of the side surface of the case 300 where the insertion hole is provided and the orientation of the side of the first antenna substrate 110 where each first cable 130 is withdrawn when the first antenna substrate 110 is attached to the case 300.

The shape of the first antenna substrate 110 is not limited to the shape according to the present embodiment. For example, the shape of the first antenna substrate 110 may be a shape having rotational symmetry with respect to the center of the first antenna substrate 110 when viewed from the third direction Z.

In an example, when viewed from the third direction Z, the shape of the first antenna substrate 110 may be a rectangle having a pair of long sides and a pair of short sides. In this example, for example, the two first cables 130 are withdrawn from one short side of the rectangle. In this case, the withdrawal direction of two first cables 130 can be changed depending on which direction the short side of the first antenna substrate 110 positioned on the side where the two first cables 130 are withdrawn is directed in.

As another example, when viewed from the third direction Z, the shape of the first antenna substrate 110 may be a regular polygon such as an equilateral triangle, a regular pentagon, a regular hexagon, or a regular octagon. In this example, for example, the two first cables 130 are withdrawn from any one side of the regular polygon. In this case, the withdrawal direction of the two first cables 130 can be changed depending on which direction one side of the first antenna substrate 110 positioned on the side where the two first cables 130 are withdrawn is directed in.

As still another example, when viewed from the third direction Z, the shape of the first antenna substrate 110 may be a circle or an ellipse. In this example, for example, the two first cables 130 are withdrawn from any portion of the circle or the ellipse. In this case, the withdrawal direction of the first cable 130 can be changed depending on which direction the portion of the first antenna substrate 110 positioned on the side where the two first cables 130 are withdrawn is directed in.

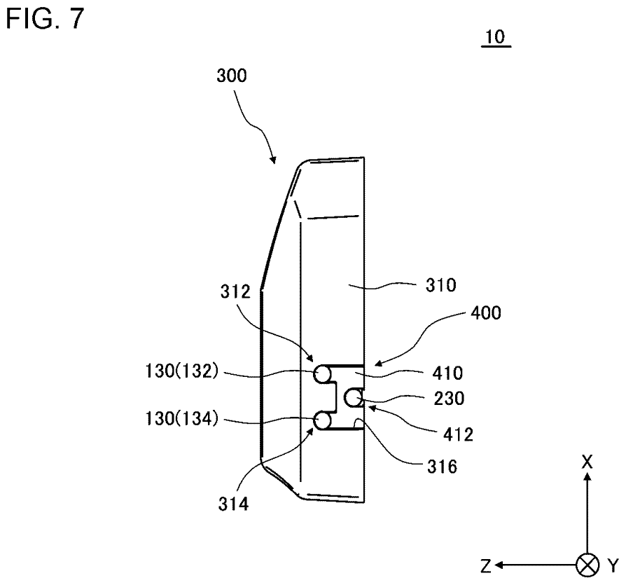

FIG. 6 is a bottom view of the antenna device 10 with the two first cables 130 and the one second cable 230 withdrawn from the first right side surface portion 310. FIG. 7 is a right side view of the antenna device 10 with the two first cables 130 and the one second cable 230 withdrawn from the first right side surface portion 310. In FIGS. 6 and 7, the bracket 500 illustrated in FIG. 1 is removed for the sake of description.

In FIG. 6, an X-marked circle indicating the third direction Z indicates that a direction from the foreground to the background of the paper plane is the positive direction of the third direction Z and that a direction from the background to the foreground of the paper plane is the negative direction of the third direction Z. In FIG. 7, an X-marked circle indicating the second direction Y indicates that a direction from the foreground to the background of the paper plane is the positive direction of the second direction Y and that a direction from the background to the foreground of the paper plane is the negative direction of the second direction Y.

A method of withdrawing the second cable 230 from the third right insertion hole 412 will be described with reference to FIG. 6. The second cable 230 is withdrawn from the third right insertion hole 412 from the upper surface side of the base member 400 through the fourth notch 402, the front insertion hole 452, the first guide groove 442, the branch portion 450, and the second guide groove 444 in the following manner.

The second cable 230 is folded back from the upper surface side of the base member 400 toward the front insertion hole 452 through the fourth notch 402. In the present embodiment, the front insertion hole 452 is displaced in the second direction Y with respect to the portion of the second cable 230 positioned on the upper surface side of the base member 400. Specifically, the portion of the second cable 230 positioned on the upper surface side of the base member 400 is positioned on the positive direction side of the second direction Y with respect to the center of the case 300 in the second direction Y. The front insertion hole 452, on the other hand, is positioned on the negative direction side of the second direction Y with respect to the center of the case 300 in the second direction Y. Accordingly, the height difference of the second cable 230 in the third direction Z can be kept small as compared with a case where the front insertion hole 452 is aligned in the second direction Y with the portion of the second cable 230 positioned on the upper surface side of the base member 400.

A method of folding the second cable 230 from the upper surface side of the base member 400 toward the front insertion hole 452 is not limited to the method according to the present embodiment. For example, the front insertion hole 452 may be aligned in the second direction Y with the portion of the second cable 230 positioned on the upper surface side of the base member 400. For example, the front insertion hole 452 may be positioned at the center of the case 300 in the second direction Y. The portion of the second cable 230 positioned on the upper surface side of the base member 400 may be positioned at the center of the case 300 in the second direction Y.

The second cable 230 is guided by the first guide groove 442 from the front insertion hole 452 to the branch portion 450. In the present embodiment, the first guide groove 442 is a path curved to meander from the front insertion hole 452 to the branch portion 450. Accordingly, the first guide groove 442 secures a curvature for bending the second cable 230 from the front insertion hole 452 to the branch portion 450 positioned at substantial the center of the base member 400 in the second direction Y, and the workability of the routing of the second cable 230 is improved.

In the present embodiment, a portion of the first guide groove 442 in the vicinity of the branch portion 450 is curved from the positive direction of the second direction Y toward the negative direction of the first direction X to guide the second cable 230 from the first guide groove 442 to the second guide groove 444. When the second cable 230 is withdrawn from the third right insertion hole 412, the second cable 230 can be therefore easily guided to the second guide groove 444 by the portion of the first guide groove 442 curved from the positive direction of the second direction Y to the negative direction of the first direction X, and the workability of the routing of the second cable 230 is improved.

In the present embodiment, a portion of the first guide groove 442 is provided with a first stopper 442a. The first stopper 442a includes protrusions protruding from both sides of the lower end of the opening of the first guide groove 442 toward the center of the opening. The provided first stopper 442a can make the second cable 230 less likely to fall out from the first guide groove 442 as compared with a case where the first stopper 442a is not provided. The first stopper 442a may not be provided.

The second cable 230 is guided by the second guide groove 444 from the branch portion 450 to the third right insertion hole 412. In the present embodiment, a portion of the second guide groove 444 in the vicinity of the branch portion 450 is curved from the negative direction of the first direction X toward the negative direction of the second direction Y to guide the second cable 230 from the first guide groove 442 to the second guide groove 444. When the second cable 230 is withdrawn from the third right insertion hole 412, the second cable 230 can be therefore easily guided to the second guide groove 444 by the portion of the second guide groove 444 curved from the negative direction of the first direction X to the negative direction of the second direction Y, and the workability of the routing of the second cable 230 is improved.

In the present embodiment, a portion of the second guide groove 444 is provided with a second stopper 444a in the same manner as the first stopper 442a of the first guide groove 442. The second stopper 444a may not be provided.

Next, a method of withdrawing the second cable 230 from the third rear insertion hole 422 will be described with reference to FIG. 6. The method of withdrawing the second cable 230 from the third rear insertion hole 422 is the same as the method of withdrawing the second cable 230 from the third right insertion hole 412 except for the following points.

In the same manner as the method of withdrawing the second cable 230 from the third right insertion hole 412, the second cable 230 is folded back from the upper surface side of the base member 400 toward the front insertion hole 452 through the fourth notch 402, and is guided from the front insertion hole 452 to the branch portion 450 by the first guide groove 442.

The second cable 230 is guided by the third guide groove 446 from the branch portion 450 to the third rear insertion hole 422. In the present embodiment, the third guide groove 446 extends from the branch portion 450 to the third rear insertion hole 422 in the first direction X. Accordingly, the second cable 230 can be withdrawn straight from the branch portion 450 to the third rear insertion hole 422.

In the present embodiment, a portion of the third guide groove 446 is provided with a third stopper 446a in the same manner as the first stopper 442a of the first guide groove 442. The third stopper 446a may not be provided.

Next, a method of withdrawing the second cable 230 from the third left insertion hole 432 will be described with reference to FIG. 6. The method of withdrawing the second cable 230 from the third left insertion hole 432 is the same as the method of withdrawing the second cable 230 from the third right insertion hole 412 except for the following points.

In the same manner as the method of withdrawing the second cable 230 from the third right insertion hole 412, the second cable 230 is folded back from the upper surface side of the base member 400 toward the front insertion hole 452 through the fourth notch 402, and is guided from the front insertion hole 452 to the branch portion 450 by the first guide groove 442.

The second cable 230 is guided by the fourth guide groove 448 from the branch portion 450 to the third left insertion hole 432. In the present embodiment, a portion of the fourth guide groove 448 in the vicinity of the branch portion 450 is curved from the negative direction of the first direction X toward the positive direction of the second direction Y to guide the second cable 230 from the first guide groove 442 to the fourth guide groove 448. When the second cable 230 is withdrawn from the third left insertion hole 432, the second cable 230 can be therefore easily guided to the fourth guide groove 448 by the portion of the fourth guide groove 448 curved from the negative direction of the first direction X to the positive direction of the second direction Y, and the workability of the routing of the second cable 230 is improved.

In the present embodiment, a portion of the fourth guide groove 448 is provided with a fourth stopper 448a in the same manner as the first stopper 442a of the first guide groove 442. The fourth stopper 448a may not be provided.

The withdrawal direction of the second cable 230 is not limited to the right side, the rear side, or the left side of the base member 400. For example, the second cable 230 may be withdrawn in another direction such as the right oblique rear side or the left oblique front side of the base member 400. The withdrawal direction of which the second cable 230 can be changed depending on the orientation of the side surface of the base member 400 where the insertion hole is provided and the shape of the guide groove provided in the base member 400.

With reference to FIG. 7, the routing of the two first cables 130 and the one second cable 230 will be described. Hereinafter, in the present embodiment, a height direction of the case 300 is a direction parallel to the third direction Z. Hereinafter, in the present embodiment, the height of the case 300 in the height direction is higher toward the positive direction of the third direction Z.

The first GNSS cable 132 and the second GNSS cable 134 are respectively withdrawn from the first right insertion hole 312 and the second right insertion hole 314 through the region on the upper surface side of the base member 400. That is, in the cable withdrawal structure according to the present embodiment, the two first cables 130 can be withdrawn from any of the first right insertion hole 312 and the second right insertion hole 314, the first rear insertion hole 322 and the second rear insertion hole 324, or the first left insertion hole 332 and the second left insertion hole 334 through the region on a side of the base member 400 opposite to the side where the first guide groove 442, the second guide groove 444, the third guide groove 446, and the fourth guide groove 448 are positioned.

In the cable withdrawal structure according to the present embodiment, the height at which the first right insertion hole 312 and the second right insertion hole 314 are positioned in the height direction of the case 300 is different from the height at which the third right insertion hole 412 is positioned in the height direction of the case 300. Specifically, the height at which the first right insertion hole 312 and the second right insertion hole 314 are positioned in the height direction of the case 300 is higher than the height at which the third right insertion hole 412 is positioned in the height direction of the case 300. Similarly, as illustrated in FIG. 2, the height at which the first rear insertion hole 322 and the second rear insertion hole 324 are positioned in the height direction of the case 300 is higher than the height at which the third rear insertion hole 422 is positioned in the height direction of the case 300. The height at which the first left insertion hole 332 and the second left insertion hole 334 are positioned in the height direction of the case 300 is higher than the height at which the third left insertion hole 432 is positioned in the height direction of the case 300.

In the present embodiment, the region in which each first cable 130 is routed and the region in which the second cable 230 is routed can be displaced in the height direction of the case 300. Accordingly, the degree of freedom of the routing of each first cable 130 and the second cable 230 can be improved as compared with a case where each first cable 130 and the second cable 230 are positioned at the same height in the height direction of the case 300.

In the present embodiment, each first cable 130 can be withdrawn from the case 300 without through the guide groove provided on the base member 400. Accordingly, the degree of freedom and the workability of the routing of the first cable 130 and the second cable 230 can be improved as compared with a case where both the first cable 130 and the second cable 230 are withdrawn from the base member 400 through the guide grooves.

In the present embodiment, each first cable 130 and the second cable 230 can be routed with at least a portion of each first cable 130 and at least a portion of the second cable 230 overlap in the height direction of the case 300. Accordingly, the footprint of each first cable 130 and the second cable 230 in the direction perpendicular to the height direction of the case 300 can be suppressed as compared with a case where each first cable 130 and the second cable 230 are positioned at the same height in the height direction of the case 300. Thus, in the present embodiment, the size increase of the case 300 in the direction perpendicular to the height direction of the case 300 can be suppressed as compared with a case where each first cable 130 and the second cable 230 are positioned at the same height in the height direction of the case 300.

In the present embodiment, the third right insertion hole 412 is positioned at a different portion from a portion of the region positioned at the same height as the third right insertion hole 412 in the height direction of the case 300 overlapping the first right insertion hole 312 and the second right insertion hole 314 in the height direction of the case 300. In other words, in the projection having the first right insertion hole 312, the second right insertion hole 314, and the third right insertion hole 412 projected in parallel with the third direction Z onto a virtual plane perpendicular to the third direction Z, the third right insertion hole 412 does not overlap the first right insertion hole 312 and the second right insertion hole 314. In the present embodiment, the third right insertion hole 412 is positioned between the portions of the region positioned at the same height as the third right insertion hole 412 in the height direction of the case 300 overlapping the first right insertion hole 312 and the second right insertion hole 314 in the height direction of the case 300. Similarly, as illustrated in FIG. 2, the third rear insertion hole 422 is positioned between the portions of the region positioned at the same height as the third rear insertion hole 422 in the height direction of the case 300 overlapping the first rear insertion hole 322 and the second rear insertion hole 324 in the height direction of the case 300. The third left insertion hole 432 is positioned between the portions of the region positioned at the same height as the third left insertion hole 432 in the height direction of the case 300 overlapping the first left insertion hole 332 and the second left insertion hole 334 in the height direction of the case 300.

In the present embodiment, the distance between the second cable 230 and each first cable 130 can be increased as compared with a case where at least a portion of the third right insertion hole 412 overlaps the first right insertion hole 312 or the second right insertion hole 314 in the height direction of the case 300. Accordingly, the workability of the routing of the first cable 130 and the second cable 230 can be improved as compared with a case where at least a portion of the third right insertion hole 412 overlaps at least a portion of the first right insertion hole 312 or the second right insertion hole 314 in the height direction of the case 300.

In the present embodiment, the withdrawal direction of the two first cables 130 and the withdrawal direction of the one second cable 230 can be independently determined. For example, the first cable 130 and the second cable 230 can be withdrawn in the same direction when the side surface of the case 300 provided with the insertion hole from which the first cable 130 is withdrawn and the side surface of the base member 400 provided with the insertion hole from which the second cable 230 is withdrawn are provided on the same side surface side. For example, all the first GNSS cable 132, the second GNSS cable 134, and the second cable 230 can be withdrawn toward the right side of the antenna device 10 by withdrawing the first GNSS cable 132 and the second GNSS cable 134 respectively from the first right insertion hole 312 and the second right insertion hole 314 and withdrawing the second cable 230 from the third right insertion hole 412. The first cable 130 and the second cable 230 can be withdrawn in different directions when the side surface of the case 300 provided with the insertion hole from which the first cable 130 is withdrawn and the side surface of the base member 400 provided with the insertion hole from which the second cable 230 is withdrawn are provided on the different sides. For example, the first GNSS cable 132 and the second GNSS cable 134 can be withdrawn to the right side of the antenna device 10, and the second cable 230 can be withdrawn to the left side of the antenna device 10 by withdrawing the first GNSS cable 132 and the second GNSS cable 134 respectively from the first right insertion hole 312 and the second right insertion hole 314 and withdrawing the second cable 230 from the third left insertion hole 432.

Embodiments of the present invention have been described with reference to the drawings; however, these are merely examples of the present invention, and various configurations other than the above-described ones can also be adopted.

For example, in the present embodiment, the first antenna 120 is the GNSS antenna. Even if the first antenna 120 is different from the GNSS antenna, however, the cable withdrawal structure according to the present embodiment may be applied in the same manner as in a case where the first antenna 120 is the GNSS antenna. In the present embodiment, the second antenna 220 is the ETC antenna. Even if the second antenna 220 is different from the ETC antenna, however, the cable withdrawal structure according to the present embodiment may be applied in the same manner as in a case where the second antenna 220 is the ETC antenna.

In the present embodiment, the two first cables 130 are connected to the first antenna 120. Even if the number of first cables 130 connected to the first antenna 120 is only one or three or more, however, the cable withdrawal structure according to the present embodiment may be applied in the same manner as in a case where the two first cables 130 are connected to the first antenna 120. In the present embodiment, one second cable 230 is connected to the second antenna 220. Even if the number of second cables 230 connected to the second antenna 220 is two or more, however, the cable withdrawal structure according to the present embodiment may be applied in the same manner as in a case where the one second cable 230 is connected to the second antenna 220.

According to this specification, the following aspects are provided.

### Aspect 1

Aspect 1 is an antenna device including:
a case;
a first antenna accommodated in the case;
a first antenna substrate provided with the first antenna; and
a first cable connected to the first antenna substrate,
in which each of a plurality of first side surfaces of the case is provided with a first insertion hole allowing withdrawal of the first cable, and
the first antenna substrate allows a withdrawal direction of the first cable to be changed with respect to the first insertion hole of each of the plurality of first side surfaces.

According to Aspect 1, the withdrawal direction of the first cable can be changed with respect to the first insertion hole of each of the plurality of first side surfaces by the first antenna substrate. Accordingly, the degree of freedom and the workability of the routing of the first cable can be improved because the withdrawal direction of the first cable can be easily changed with respect to the first insertion hole of each of the plurality of first side surfaces.

### Aspect 2

Aspect 2 is the antenna device described in Aspect 1,
in which the first antenna substrate allows the withdrawal direction of the first cable to be changed with the first cable connected to the first antenna substrate.

According to Aspect 2, even if the first cable is connected to the first antenna substrate, the degree of freedom and the workability of the routing of the first cable can be improved similarly to Aspect 1 as compared with a case where the withdrawal direction of the first cable is changed with respect to the first insertion hole of each of the plurality of first side surfaces by a configuration different from the first antenna substrate.

### Aspect 3

Aspect 3 is the antenna device described in Aspect 1 or 2, further including:
a second antenna accommodated in the case;
a second antenna substrate provided with the second antenna;
a second cable connected to the second antenna substrate; and
a base member provided with a guide groove for guiding the second cable,
in which each of a plurality of second side surfaces of the base member is provided with a second insertion hole allowing withdrawal of the second cable from the guide groove, and
each of the plurality of second side surfaces is provided on the same side as each of the plurality of first side surfaces.

According to Aspect 3, the first cable and the second cable can be withdrawn in the same direction when the first side surface of the case provided with the first insertion hole from which the first cable is withdrawn and the second side surface of the base member provided with the second insertion hole from which the second cable is withdrawn are provided on the same side.

### Aspect 4

Aspect 4 is the antenna device described in Aspect 3,
in which each of the plurality of first side surfaces has a notch communicating with the first insertion hole, and
each of the plurality of second side surfaces fitting into the notch positions the first insertion hole and the second insertion hole on the same first side surface side.

According to Aspect 4, the height of the antenna device can be reduced, for example, as compared with a case where the notch is not provided and the second side surface is displaced from the first side surface in the height direction of the case.

### Aspect 5

The antenna device described in Aspect 3 or 4,
in which a height at which the first insertion hole is positioned in a height direction of the case is different from a height at which the second insertion hole is positioned in the height direction of the case.

According to Aspect 5, the first cable and the second cable can be routed with at least a portion of the first cable and at least a portion of the second cable overlapping in the height direction of the case. Accordingly, the footprint of the first cable and the second cable in the direction perpendicular to the height direction of case can be reduced as compared with a case where the first insertion hole and the second insertion hole are at the same height in the height direction of the case. Thus, the size increase of the case in the direction perpendicular to the height direction of the case can be suppressed as compared with a case where the first insertion hole and the second insertion hole are at the same height in the height direction of the case.

### Aspect 6

Aspect 6 is the antenna device described in Aspect 5,
in which the height at which the first insertion hole is positioned in the height direction of the case is higher than the height at which the second insertion hole is positioned in the height direction of the case.

According to Aspect 6, the first cable can be withdrawn from the first insertion hole through a space above the base member.

### Aspect 7

Aspect 7 is the antenna device described in Aspect 5 or 6,
in which the second insertion hole is positioned at a different portion from a portion of a region positioned at the same height as the second insertion hole in the height direction of the case overlapping the first insertion hole in the height direction of the case.

According to Aspect 7, the distance between the first insertion hole and the second insertion hole can be reduced as compared with a case where at least a portion of the second insertion hole overlaps at least a portion of the first insertion hole in the height direction of the case. Accordingly, the workability of the routing of the first cable and the second cable can be improved as compared with a case where at least a portion of the second insertion hole overlaps at least a portion of the first insertion hole in the height direction of the case.

### Aspect 8

Aspect 8 is the antenna device described in any one of Aspects 3 to 7,
in which the first cable is withdrawable from the first insertion hole through a region on a side opposite to a side of the base member where the guide groove is positioned.

According to Aspect 8, the first cable can be withdrawn from the case without through the guide groove. Accordingly, the degree of freedom and the workability of the routing of the first cable and the second cable can be improved as compared with a case where both the first cable and the second cable are withdrawn from the base member through the guide grooves.

### Aspect 9

Aspect 9 is a cable withdrawal structure to withdraw a first cable from a case, the first cable being connected to a first antenna substrate provided with a first antenna, the case accommodating the first antenna and the first antenna substrate, the cable withdrawal structure including:
a first insertion hole provided in each of a plurality of first side surfaces of the case, the first insertion hole allowing withdrawal of the first cable; and
a change portion provided on at least the first antenna substrate and allowing a withdrawal direction of the first cable to be changed with respect to the first insertion hole of each of the plurality of first side surfaces.

According to Aspect 9, the degree of freedom and the workability of the routing of the first cable can be improved similarly to Aspect 1 because the withdrawal direction of the first cable can be easily changed with respect to the first insertion hole of each of the plurality of first side surfaces.

### Aspect 10

Aspect 10 is an antenna device including:
a case;
a plurality of antennas accommodated in the case;
a plurality of cables connected to the plurality of antennas; and
a base member provided with a guide groove for guiding at least one of the plurality of cables,
in which at least another one of the plurality of cables is withdrawn from the case through a region positioned on a side opposite to a side of the base member where the guide groove is positioned.

According to Aspect 10, at least one of the plurality of cables can be withdrawn from the base member through the guide groove. At least another one of the plurality of cables can be withdrawn from the case without through the guide groove. Accordingly, the degree of freedom and the workability of the routing of the plurality of cables can be improved as compared with a case where any of the plurality of cables is withdrawn from the base member through the guide groove.

### Aspect 11

Aspect 11 is a cable withdrawal structure including:
a case accommodating a plurality of antennas to which a plurality of cables are connected; and
a base member provided with a guide groove for guiding at least one of the plurality of cables,
in which at least another one of the plurality of cables is withdrawn from the case through a region positioned on a side opposite to a side of the base member where the guide groove is positioned.

According to Aspect 11, the degree of freedom and the workability of the routing of the plurality of cables can be improved similarly to Aspect 9 as compared with a case where all the plurality of cables are withdrawn from the base member through the guide grooves.

This application claims priority based on Japanese Application No. 2021-156279, filed Sep. 27, 2021, the entire disclosure of which is incorporated herein by reference.

### REFERENCE SIGNS LIST

10 antenna device, 100 first antenna unit, 110 first antenna substrate, 110a first side, 110b second side, 110c third side, 110d fourth side, 112a first hole, 112b second hole, 112c third hole, 112d fourth hole, 120 first antenna, 122 shield cover, 130 first cable, 132 first GNSS cable, 134 second GNSS cable, 200 second antenna unit, 210 second antenna substrate, 220 second antenna, 230 second cable, 232 first end, 300 case, 302 attachment hole, 304a first protrusion, 304b second protrusion, 310 first right side surface portion, 312 first right insertion hole, 314 second right insertion hole, 316 first notch, 320 first rear side surface portion, 322 first rear insertion hole, 324 second rear insertion hole, 326 second notch, 330 first left side surface portion, 332 first left insertion hole, 334 second left insertion hole, 336 third notch, 400 base member, 402 fourth notch, 410 second right side surface portion, 412 third right insertion hole, 420 second rear side surface portion, 422 third rear insertion hole, 430 second left side surface portion, 432 third left insertion hole, 442 first guide groove, 442a first stopper, 444 second guide groove, 444a second stopper, 446 third guide groove, 446a third stopper, 448 fourth guide groove, 448a fourth stopper, 450 branch portion, 452 front insertion hole, 500 bracket, 502 through-hole, 504 screw, X first direction, Y second direction, Z third direction

1. An antenna device comprising:
a case;
a first antenna accommodated in the case;
a first antenna substrate provided with the first antenna; and
a first cable connected to the first antenna substrate,
wherein each of a plurality of first side surfaces of the case is provided with a first insertion hole allowing withdrawal of the first cable, and
the first antenna substrate allows a withdrawal direction of the first cable to be changed with respect to the first insertion hole of each of the plurality of first side surfaces.

2. The antenna device according to claim 1,
wherein the first antenna substrate allows the withdrawal direction of the first cable to be changed with the first cable connected to the first antenna substrate.

3. The antenna device according to claim 1, further comprising:
a second antenna accommodated in the case;
a second antenna substrate provided with the second antenna;
a second cable connected to the second antenna substrate; and
a base member provided with a guide groove for guiding the second cable,
wherein each of a plurality of second side surfaces of the base member is provided with a second insertion hole allowing withdrawal of the second cable from the guide groove, and
each of the plurality of second side surfaces is provided on the same side as each of the plurality of first side surfaces.

4. The antenna device according to claim 3,
wherein each of the plurality of first side surfaces has a notch communicating with the first insertion hole, and
each of the plurality of second side surfaces fitting into the notch positions the first insertion hole and the second insertion hole on the same first side surface side.

5. The antenna device according to claim 3,
wherein a height at which the first insertion hole is positioned in a height direction of the case is different from a height at which the second insertion hole is positioned in the height direction of the case.

6. The antenna device according to claim 5,
wherein the height at which the first insertion hole is positioned in the height direction of the case is higher than the height at which the second insertion hole is positioned in the height direction of the case.

7. The antenna device according to claim 5,
wherein the second insertion hole is positioned at a different portion from a portion of a region positioned at the same height as the second insertion hole in the height direction of the case overlapping the first insertion hole in the height direction of the case.

8. The antenna device according to claim 3,
wherein the first cable is withdrawable from the first insertion hole through a region on a side opposite to a side of the base member where the guide groove is positioned.

9. A cable withdrawal structure to withdraw a first cable from a case, the first cable being connected to a first antenna substrate provided with a first antenna, the case accommodating the first antenna and the first antenna substrate, the cable withdrawal structure comprising:
a first insertion hole provided in each of a plurality of first side surfaces of the case, the first insertion hole allowing withdrawal of the first cable; and
a change portion provided on at least the first antenna substrate and allowing a withdrawal direction of the first cable to be changed with respect to the first insertion hole of each of the plurality of first side surfaces.
